(19) United States
(12) Patent Application Publication
(10) Pub. No.: US 2025/0341575 A1
(43) Pub. Date: Nov. 6, 2025

(54) APPARATUS, SYSTEM, AND COMPUTER-IMPLEMENTED METHOD FOR AUTOMATICALLY DETERMINING DEGRADATION OF AN ELECTRICAL CONTACTOR

(71) Applicant: HONEYWELL INTERNATIONAL INC., Charlotte, NC (US)

(72) Inventors: Prince Ashwin Kumar Anburaj JAYAKUMAR, Charlotte, NC (US); Sharath N. RAO, Charlotte, NC (US); Nirmal A. KUMAR, Charlotte, NC (US)

(21) Appl. No.: 19/175,683

(22) Filed: Apr. 10, 2025

(30) Foreign Application Priority Data
May 3, 2024 (IN) 202411035175

(51) Int. Cl. G01R 31/327; H01H 1/20; H01H 9/50

(52) U.S. Cl. CPC G01R 31/3277; H01H 1/2066; H01H 9/50

(57) ABSTRACT

An example apparatus, computer-implemented method, and electrical system for determining a condition of an electrical contactor are provided. The example apparatus includes field monitoring circuitry, temperature monitoring circuitry, and light monitoring circuitry, each positioned near an electrical contactor and configured to determine an electric field, a contactor temperature, and a light output, respectively. The example apparatus is further configured to identify a plurality of arc events of the electrical contactor based at least in part on the electric field, the contactor temperature, and the light output. Further, a condition of the electrical contactor is determined based at least in part on a frequency of the plurality of arc events.

### CROSS-REFERENCE TO RELATED APPLICATIONS

This application claims priority pursuant to 35 U.S.C. 119(a) to Indian Patent Application number 202411035175, filed May 3, 2024, which application is incorporated herein by reference in its entirety.

### TECHNOLOGICAL FIELD

Embodiments of the present disclosure relate generally to electrical contactors, and more particularly, to leveraging an arc sensing system to determine degradation of an electrical contactor.

### BACKGROUND

Applicant has identified many technical challenges and difficulties associated with determining the degradation of electrical contactors at an early stage. Through applied effort, ingenuity, and innovation, Applicant has solved problems related to determining degradation of electrical contactors by developing solutions embodied in the present disclosure, which are described in detail below.

### BRIEF SUMMARY

Various embodiments are directed to an example apparatus, computer-implemented method, and electrical system for determining a condition of an electrical contactor. An example apparatus is provided. The example apparatus comprises field monitoring circuitry positioned proximate an electrical contactor and configured to determine an electric field proximate the electrical contactor; temperature monitoring circuitry positioned proximate the electrical contactor and configured to determine a contactor temperature proximate the electrical contactor; and light monitoring circuitry positioned proximate the electrical contactor and configured to determine a light output proximate the electrical contactor. In addition, a plurality of arc events of the electrical contactor are identified based at least in part on the electric field, the contactor temperature, and the light output. Further, a condition of the electrical contactor is determined based at least in part on a frequency of the plurality of arc events.

In some embodiments, the apparatus further comprises current detection circuitry, wherein the current detection circuitry is configured to determine a current through the electrical contactor.

In some embodiments, the current detection circuitry comprises a plurality of current sensing elements comprising at least a first current sensing element and a second current sensing element, wherein the first current sensing element is positioned at a first distance from the electrical contactor and the second current sensing element is positioned at a second distance from the electrical contactor, and wherein the second distance is greater than the first distance.

In some embodiments, the condition of the electrical contactor is determined based at least in part on the current through the electrical contactor.

In some embodiments, the field monitoring circuitry comprises a field sensing capacitor.

In some embodiments, the temperature monitoring circuitry comprises a positive temperature coefficient (PTC) sensor.

In some embodiments, the light monitoring circuitry comprises a photoresistor.

In some embodiments, the plurality of arc events are classified according to an arc event type.

In some embodiments, the arc event type comprises at least one of a field emission arc event, a thermionic emission arc event, and a spark event.

In some embodiments, the condition of the electrical contactor is a degraded condition.

In some embodiments, the condition is determined based at least in part on an amplitude of the plurality of arc events.

An example computer-implemented method for determining a condition of an electrical contactor is further provided. In some embodiments, the example computer-implemented method, may comprise determining an electric field proximate an electrical contactor based on field monitoring circuitry positioned proximate the electrical contactor; determining a contactor temperature proximate an electrical contactor based on temperature monitoring circuitry positioned proximate the electrical contactor; and determining a light output proximate an electrical contactor based on light monitoring circuitry positioned proximate the electrical contactor. In some embodiments, the example computer-implemented method may further comprise identifying a plurality of arc events based at least in part on the electric field, the contactor temperature, and the light output; and determining the condition of the electrical contactor based at least in part on a frequency of the plurality of arc events.

In some embodiments, the computer-implemented method further comprises determining a current through the electrical contactor based on current detection circuitry positioned proximate the electrical contactor.

In some embodiments, the condition of the electrical contactor is determined based at least in part on the current through the electrical contactor.

In some embodiments, the field monitoring circuitry comprises a field sensing capacitor.

In some embodiments, the temperature monitoring circuitry comprises a positive temperature coefficient (PTC) sensor.

In some embodiments, the light monitoring circuitry comprises a photoresistor.

In some embodiments, the computer-implemented method further comprises classifying the plurality of arc events according to an arc event type.

In some embodiments, the arc event type comprises at least one of a field emission arc event, a thermionic emission arc event, and a spark event.

An example electrical system is further provided. In some embodiments, the example electrical system comprises an electrical contactor configured to selectively provide an electrical connection between a power source and an electrical load; field monitoring circuitry positioned proximate the electrical contactor and configured to determine an electric field proximate the electrical contactor; temperature monitoring circuitry positioned proximate the electrical contactor and configured to determine a contactor temperature proximate the electrical contactor; and light monitoring circuitry positioned proximate the electrical contactor and configured to determine a light output proximate the electrical contactor. In addition, the example electrical system may include a controller configured to: determine an electric field proximate an electrical contactor based on field monitoring circuitry positioned proximate the electrical contactor; determine a contactor temperature proximate an electrical contactor based on temperature monitoring circuitry positioned proximate the electrical contactor; determine a light output proximate an electrical contactor based on light monitoring circuitry positioned proximate the electrical contactor; identify a plurality of arc events based at least in part on the electric field, the contactor temperature, and the light output; and determine a condition of the electrical contactor based at least in part on a frequency of the plurality of arc events.

### BRIEF DESCRIPTION OF THE DRAWINGS

Reference will now be made to the accompanying drawings. The components illustrated in the figures may or may not be present in certain embodiments described herein. Some embodiments may include fewer (or more) components than those shown in the figures in accordance with an example embodiment of the present disclosure.

FIG. 1 illustrates a cross-section view of an example electrical contactor in accordance with an example embodiment of the present disclosure;

FIG. 2 depicts a block diagram of an example electrical contactor monitoring system in accordance with an example embodiment of the present disclosure;

FIG. 3 illustrates a block diagram of an example arc sensing system in accordance with an example embodiment of the present disclosure;

FIG. 4 illustrates an example embodiment of an arc sensing system in accordance with an example embodiment of the present disclosure;

FIG. 5 illustrates an example embodiment of current detection circuitry in an arc sensing system in accordance with an example embodiment of the present disclosure;

FIG. 6 depicts a graph of example arc events over time in accordance with an example embodiment of the present disclosure;

FIG. 7 illustrates a block diagram of an example controller in accordance with an example embodiment of the present disclosure;

FIG. 8 illustrates a flowchart of an example process for determining a condition of an electrical contactor in accordance with an example embodiment of the present disclosure; and,

FIG. 9 illustrates a block diagram of example components of a controller in accordance with an example embodiment of the present disclosure.

### DETAILED DESCRIPTION

Example embodiments will be described more fully hereinafter with reference to the accompanying drawings, in which some, but not all embodiments of the inventions of the disclosure are shown. Indeed, embodiments of the disclosure may be embodied in many different forms and should not be construed as limited to the embodiments set forth herein; rather, these embodiments are provided so that this disclosure will satisfy applicable legal requirements. Like numbers refer to like elements throughout.

Various example embodiments address technical problems associated with determining a condition of an electrical contactor during operation. As understood by those of skill in the field to which the present disclosure pertains, there are numerous example scenarios in which an electrical contactor may benefit from an automated means to detect degradation.

In general, electrical contactors provide a conductive path between a power source and an electrical load that may be selectively enabled. In some embodiments, a conductive portion of the electrical contactor may be pushed into contact with a power source line and an electrical load line, to provide the conductive path, and removed from contact with the power source line and the electrical load line when the conductive path is to be broken. In one example, electrical contactors may be utilized in an automobile to connect a power source (e.g., battery) to one or more electrical loads, such as primary traction motors, lighting systems, and infotainment systems of the automobile.

Electrical contactors used for connecting and disconnecting an electrical load to a power source greater than fifteen volts with a current of at least one amp has a high probability of causing an arc event. In electrical contactors, arc events occur during the make or break transitions of the conductive contact pads of the electrical contactor. During the make or break transitions, air between the conductive contact pads reaches a high temperature due to thermionic and field emissions. An arc event is an electrical breakdown of the gas (e.g., air) between conductive components, enabling a prolong electrical discharge between the conductive components. An arc event produces a plasma from the gas which often produces a visible light or glow.

Arc events may result in spot welding on portions of the conductive contact pads of the electrical contactors. Frequency of arc events on an electrical contactor may be increased due to metallic debris formed on the conductive contact pads from aging and/or corrosion. Welding may begin as micro-welding, accompanied by loss of material, and eventually lead to a permanent weld of the conductive contact pads. Permanent welds inhibit any ability for the electrical contactor to break an electrical connection between the power source and the electrical load. Failing to break the electrical connection between the power source and the electrical load may cause hazardous conditions, for example, the inability to disconnect a power source during a thermal runaway event.

In some examples, manufacturer's utilize multiple electrical contactors connected in series as a fail-safe to a single failed electrical contactor. In such an alternative, at least one additional electrical contactor is likely to continue to function, even if an electrical contactor fails. However, including multiple electrical contactors connected in series may be expensive. In addition, multiple electrical contactors may occupy more space which may be problematic in some environments. Further, multiple electrical contactors may fail simultaneously or in close time proximity, resulting in a hazardous condition.

The various example embodiments described herein utilize various sensing devices in an arc sensing system to monitor an electrical contactor. In some embodiments, an arc sensing system may include field monitoring circuitry configured to monitor an electrical field proximate the electrical contactor, temperature monitoring circuitry configured to monitor a temperature proximate the electrical contactor, and light monitoring circuitry configured to monitor light output proximate the electrical contactor. Utilizing the electric field, temperature, and light output, an electrical contactor monitoring system may identify, classify, and analyze arc events occurring at the electrical contactor. In some embodiments, the electrical contactor monitoring system may monitor, the frequency, duration, type, amplitude, and other characteristics of the arc events occurring at the electrical contactor. Based on the characteristics of the arc events, the electrical contactor monitoring system may determine the condition of the electrical contactor. For example, an electrical contactor monitoring system may determine an instance in which micro-welding has or is occurring, indicating the electrical contactor is in a degraded condition and a permanent weld may be likely to occur.

In addition, in some embodiments, the arc sensing system of the electrical contactor monitoring system may include current detection circuitry. Current detection circuitry included with the arc sensing system may enable the arc sensing system to determine the current through the electrical contactor. The current through the electrical contactor may be utilized to determine the arc event type. In addition, in some embodiments, the frequency of arc events may vary based on the current through the electrical contactor. The electrical contactor monitoring system may be configured to utilize the current through the electrical contactor to further determine the condition of the electrical contactor.

As a result of the herein described example embodiments and in some examples, the safety of an electrical contactor may be greatly improved. In addition, the space and cost utilized to ensure proper operation of an electrical contactor may be greatly reduced.

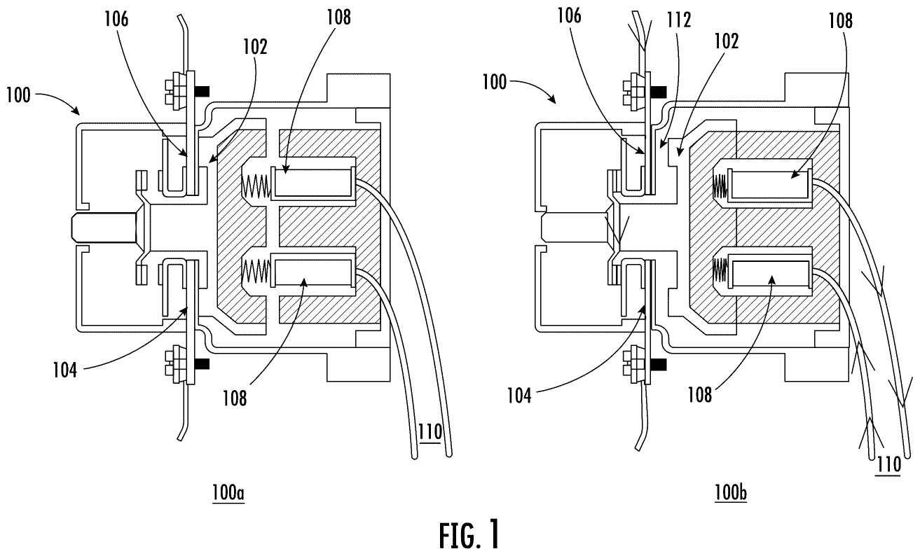

Referring now to FIG. 1, an example electrical contactor 100 in a connected state 100a and a disconnected state 100b is provided. As shown in FIG. 1, the example electrical contactor 100 includes solenoids 108 configured to change the position of the conductive contact pad 102 based on received control signals 110. As further depicted in FIG. 1, the example electrical contactor 100 includes a power source contact 106 and a load contact 104. In the connected state 100a, the solenoids 108 are extended, pushing the conductive contact pad 102 into contact with the load contact 104 and the power source contact 106, making an electrical connection between the load contact 104 and the power source contact 106. In the disconnected state 102b, the solenoids 108 are retracted, creating a gap 112 between the conductive contact pad 102 and the load contact 104 and power source contact 106, breaking the electrical connection between the load contact 104 and the power source contact 106.

As depicted in FIG. 1, the electrical contactor 100 is configured to selectively provide an electrically conductive path between a power source (not pictured) and a load (not pictured) based on received control signals 110. The connected state 100a and disconnected state 100b are controlled by a plurality of solenoids 108. A solenoid 108 is any electrical or electro-mechanical device configured to convert electrical energy into mechanical work. As depicted in FIG. 1, the solenoids 108 may move the conductive contact pad 102 toward the load contact 104 and power source contact 106 in an instance in which the control signals 110 cause the solenoids 108 to expand, creating a conductive path through the electrical contactor 100. In addition, the solenoids 108 may reposition the conductive contact pad 102 such that a gap 112 is formed between the conductive contact pad 102 and the contact surfaces (e.g., power source contact 106, load contact 104), disconnecting the conductive path through the electrical contactor 100.

Although the electrical contactor 100 depicted in FIG. 1 uses two solenoids 108 to make and break the conductive path through the electrical contactor 100 any number of solenoids 108 or other electro-mechanical devices may be used to make and break the conductive path.

As the conductive contact pad 102 transitions toward or away from the contact surfaces, and the gap 112 increases or decreases, arc events may occur. An arc event is any electrical breakdown of gas (e.g., air) between conductive components (e.g., between the conductive contact pad 102 and the power source contact 106 and/or between the conductive contact pad 102 and the load contact 104), enabling a prolong electrical discharge between the conductive components. An arc event may produce a plasma from the gas which often produces a visible light or glow. During the make or break transitions of the conductive contact pad 102, air between the conductive contact pad 102 and the conductive surfaces reaches a high temperature due to thermionic and field emissions.

Arc events may be classified as different arc types depending on the conditions facilitating the arc event, the duration of the arc, the current through the electrical contactor 100, the voltage difference between the conductive contact pad 102 and the contact surfaces, the duration of the arc event, and other factors. Example arc event types may include field emission arc events, thermionic emission arc events, and spark events.

In general, arc events may be classified by the kinetic energy source enabling electrons to jump the gap 112 between conductive components. For example, in some embodiments, electrons may gain kinetic energy due to an external voltage field present in the electrical contactor 100. An arc event in which the kinetic energy source enabling electrons to jump the gap 112 is an external voltage field may be classified as a field emission arc event. In some embodiments, electrons may gain kinetic energy due to external heat present in the electrical contactor 100. An arc event in which the kinetic energy source enabling electrons to jump the gap 112 is external heat may be classified as a thermionic emission arc event.

Further, arc events may be classified by the duration of the arc event. A spark event occurs for a short duration. In general, a field emission arc event or a thermionic emission arc event is a continuous discharge between the conductive contact pad 102 and the contact surfaces. However, a spark event is a short-duration, momentary discharge. In some embodiments, a spark event may be distinguished from a field emission arc event, or a thermionic emission arc event based on the duration of the visible light or glow, and/or the current in the electrical contactor.

Arc events may be an indicator of a condition of an electrical contactor 100. For example, arc events may provide insight into the degradation of the conductive contact pad and other conductive surfaces of the electrical contactor 100. In some embodiments, due to age and corrosion, an electrical contactor 100 may form metallic debris on the conductive contact pad 102 and/or one or more conductive surfaces. The formation of metallic debris may increase the frequency and/or amplitude of arc events in an electrical contactor 100.

In addition, arc events may increase the temperature at or near the surface of the conductive contact pad 102 and the contact surfaces. During arc events, the conductive surfaces and/or the conductive contact pad 102 may soften, melt, or boil. Repeatedly softening the conductive surfaces and re-cooling may result in spot welding or micro welding of a conductive contact pad 102 to one or more conductive surfaces. Micro welding is an indicator of a degraded condition of an electrical contactor 100 in which the conductive contact pad 102 is temporarily adhered to the surface of the power source contact 106 and/or the load contact 104. Micro welds may be broken in an instance in which the conductive contact pad 102 is retracted, however, micro welds may be an early indicator of permanent welds. Micro welding may also result in loss of material on and around the conductive surfaces. The loss of material may result in degraded performance of the electrical contactor 100. Loss of material is also an early indicator of a degraded condition resulting in a failed electrical contactor 100.

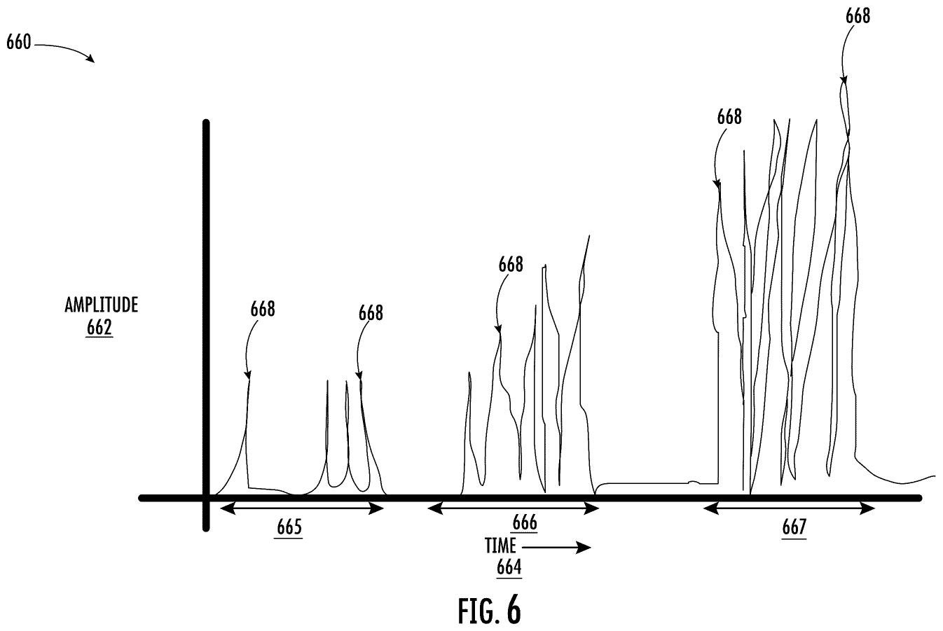

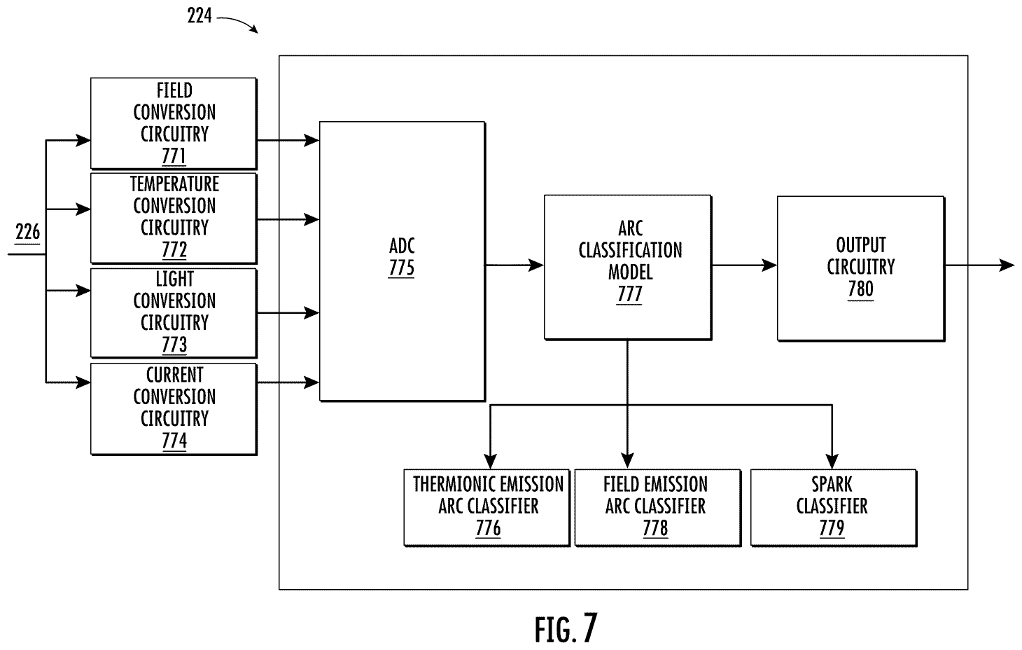

Permanent welding is another indicator of an electrical contactor 100 in a degraded condition. Permanent welding is any condition in which the conductive contact pad 102 is permanently adhered to one or more contact surfaces (e.g., power source contact 106, load contact 104). Permanent welding prevents the solenoids 108 from breaking the electrical connection formed between the power source contact 106 and the load contact 104 by the conductive contact pad 102. Permanent welding may result in a dangerous electrical contactor 100 condition. For example, in an instance in which the power source contact 106 is electrically coupled to a battery entering into thermal runaway. In such an instance, one mitigating tactic to slow the onset of thermal runaway is to disconnect the electrical load, for example, an electrical load electrically coupled to the load contact 104. In a permanent weld state, the electrical contact to the electrical load is unable to be broken. In such an instance, the onset of thermal runway may continue, resulting in a catastrophic event. The identification of a degraded condition of an electrical contactor 100 based on arc events is further described in relation to FIG. 6 and FIG. 7.

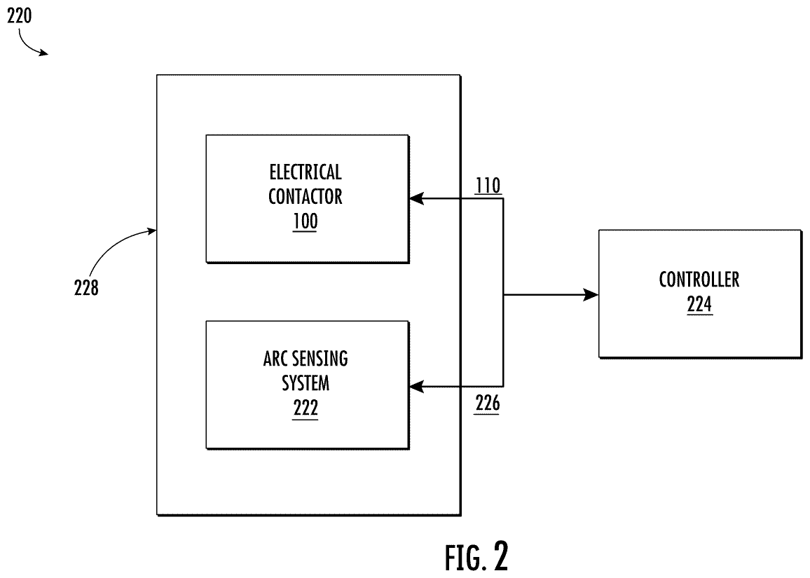

Referring now to FIG. 2, an example electrical contactor monitoring system 220 is provided. As depicted in FIG. 2, the example electrical contactor monitoring system 220 includes an electrical contactor 100 and an arc sensing system 222 comprising an electrical contactor device 228. In addition, a controller 224 is electrically coupled to the electrical contactor device 228 and configured to provide control signals 110 to the electrical contactor 100 and receive arc sensing data 226 from the arc sensing system 222.

As depicted in FIG. 2, the example electrical contactor monitoring system 220 includes an electrical contactor device 228. An electrical contactor device 228 is any housing, packaging, cavity, space, etc. comprising at least an electrical contactor 100 and an arc sensing system 222. Although not depicted in FIG. 2, in some embodiments, the electrical contactor device 228 may further include the controller 224. The electrical contactor device 228 positions the arc sensing system 222 in close proximity to the electrical contactor 100. In some embodiments, the electrical contactor device 228 may provide packaging and/or a housing, protecting the components of the electrical contactor device 228 from an external environment.

As further depicted in FIG. 2, the electrical contactor 100 of the electrical contactor device 228 is configured to receive control signals 110 from the controller 224. Control signals 110 are any electrical signals transmitted by the controller 224 to control the state of the electrical contactor 100. For example, control signals 110 are transmitted to the electrical contactor 100 to move the conductive pad of the electrical contactor 100 to and from a connected/disconnected state.

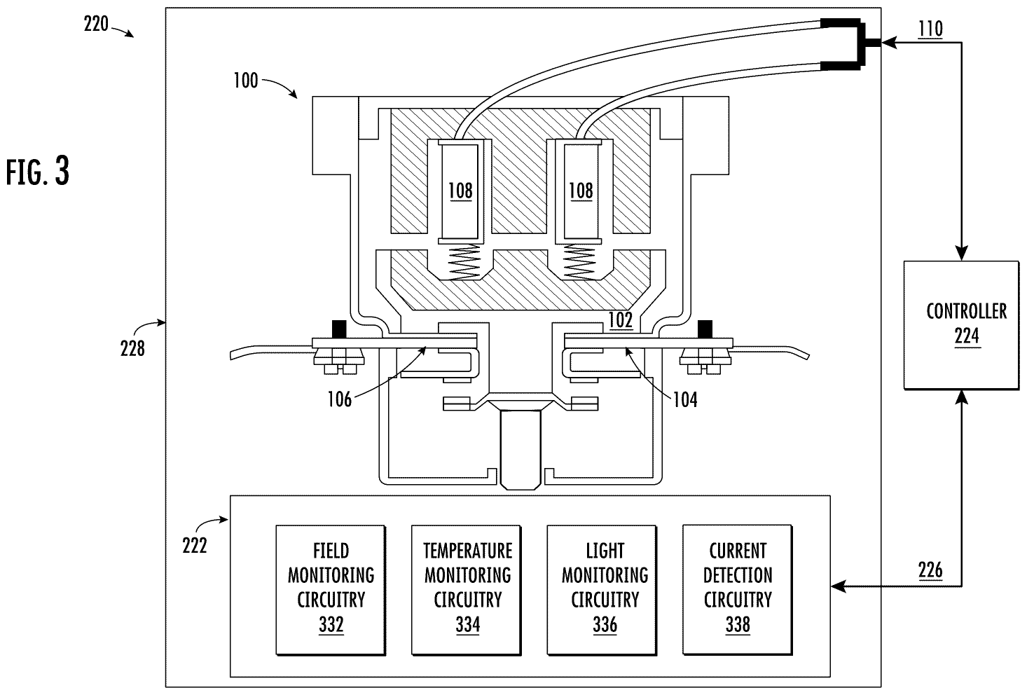

As further depicted in FIG. 2, the example electrical contactor device 228 includes an arc sensing system 222. An arc sensing system 222 is any combination of sensing devices positioned proximate the electrical contactor 100 and configured to generate arc sensing data 226 based on one or more physical characteristics of the environment proximate the electrical contactor 100. Physical characteristics proximate the electrical contactor 100 may include temperature, electric field, magnetic field, light output, current in the electrical contactor 100, voltage in the electrical contactor 100, and so on. The arc sensing system 222 is further described in relation to FIG. 3-FIG. 5.

As further depicted in FIG. 2, the arc sensing system 222 transmits arc sensing data 226. Arc sensing data 226 comprises electrical signals representing one or more physical characteristics proximate the electrical contactor 100. Arc sensing data 226 may be configured to transmit data related to the various physical characteristics proximate the electrical contactor 100 such as temperature, electric field, magnetic field, light output, current in the electrical contactor 100, voltage in the electrical contactor 100, and so on. Arc sensing data 226 may comprise digital and/or analog electrical signals. In some embodiments, the arc sensing data 226 may be amplified, cleaned, or otherwise filtered before being transmitted to the controller 224.

As further depicted in FIG. 2, the example electrical contactor monitoring system 220 includes a controller 224. The controller 224 is configured to receive arc sensing data 226 indicating various physical characteristics of the environment proximate the electrical contactor 100. The controller 224 is configured to process the arc sensing data 226 and identify arc events, including arc event types. The controller 224 is further configured to determine a degraded condition of the electrical contactor based on the frequency and amplitude of arc events, as well as the arc event types. For example, the controller 224 may determine the electrical contactor 100 is experiencing a micro welding based on an increased frequency and/or amplitude of arc events. The functionality of the controller 224 is described further in relation to FIG. 7-FIG. 9. In addition, the controller 224 is configured to transmit control signals 110 to update the state of the electrical contactor 100. For example, to transition the electrical contactor 100 from a connected state to a disconnected state and vice versa.

Referring now to FIG. 3, an example embodiment of an electrical contactor monitoring system 220 is provided. As depicted in FIG. 3, the example electrical contactor monitoring system 220 includes an electrical contactor device 228 comprising an electrical contactor 100 and an arc sensing system 222. The arc sensing system 222 comprises field monitoring circuitry 332, temperature monitoring circuitry 334, light monitoring circuitry 336, and current detection circuitry 338, each configured to generate arc sensing data 226. As further depicted in FIG. 3, the example electrical contactor monitoring system 220 includes a controller 224 configured to receive arc sensing data 226 from the arc sensing system 222 and transmit control signals 110 to the electrical contactor 100.

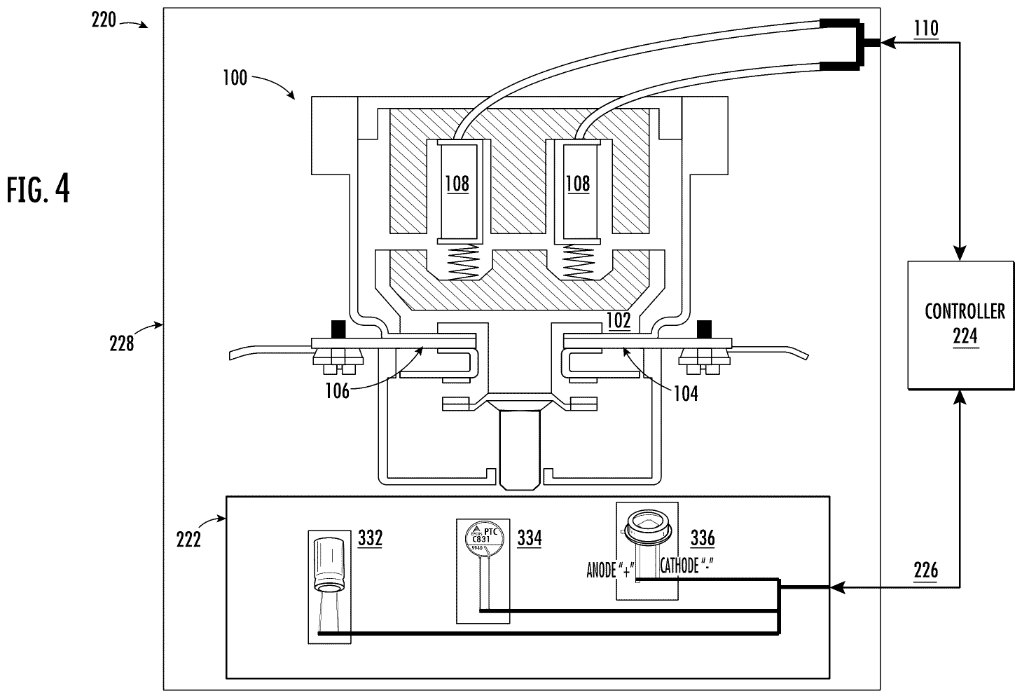

As depicted in FIG. 3, the example arc sensing system 222 of the electrical contactor device 228 of the electrical contactor monitoring system 220 includes field monitoring circuitry 332. Field monitoring circuitry 332 is any circuitry including hardware and/or software configured to measure the electric field proximate the electrical contactor 100. Field monitoring circuitry 332 may utilize passive electrical components, such as capacitors, probes, or other devices to determine the electric field proximate the electrical contactor 100. The electric field at or near the electrical contactor 100 may indicate the occurrence and/or type of an arc event. For example, an increase in the electric field at or near the electrical contactor 100 accompanied by an increase in light output may indicate a field emission type arc event. An example embodiment of field monitoring circuitry 332 is depicted in FIG. 4.

As further depicted in FIG. 3, the example arc sensing system 222 of the electrical contactor device 228 of the electrical contactor monitoring system 220 includes temperature monitoring circuitry 334. Temperature monitoring circuitry 334 is any circuitry including hardware and/or software configured to measure the contactor temperature. The contactor temperature represents the temperature at or proximate to the electrical contactor 100. Temperature monitoring circuitry 334 may utilize passive electrical components, such as resistive elements to determine the temperature proximate the electrical contactor 100. The temperature at or near the electrical contactor 100 may indicate the occurrence and/or type of an arc event. For example, an increase in the temperature at or near the electrical contactor 100 accompanied by an increase in light output may indicate a thermionic emission type arc event. An example embodiment of temperature monitoring circuitry 334 is depicted in FIG. 4.

As further depicted in FIG. 3, the example arc sensing system 222 of the electrical contactor device 228 of the electrical contactor monitoring system 220 includes light monitoring circuitry 336. Light monitoring circuitry 336 is any circuitry including hardware and/or software configured to measure the light output proximate the electrical contactor 100. Light monitoring circuitry 336 may utilize passive electrical components, such as a photodiode to determine the light output proximate the electrical contactor 100. The light output is representative of the intensity of light emanating from the electrical contactor at a given point in time. The light output at or near the electrical contactor 100 may indicate the occurrence and/or type of an arc event. For example, a short duration of light output may indicate a spark event, while a longer duration of light output may indicate a field emission arc event or a thermionic emission arc event. An example embodiment of light monitoring circuitry 336 is depicted in FIG. 4.

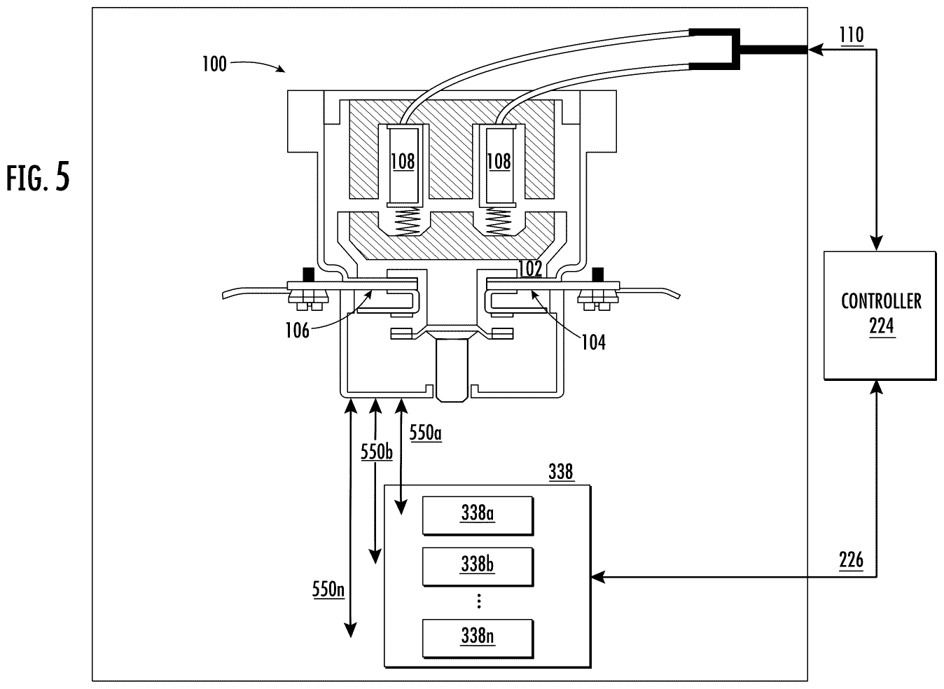

As further depicted in FIG. 3, the example arc sensing system 222 of the electrical contactor device 228 of the electrical contactor monitoring system 220 includes current detection circuitry 338. Current detection circuitry 338 is any circuitry including hardware and/or software configured to measure the current passing through the electrical contactor 100. Current detection circuitry 338 may utilize passive electrical components, such as Hall effect elements to determine the current through the electrical contactor 100. The current through the electrical contactor 100 may indicate the occurrence and/or type of an arc event. For example, certain arc events may only occur above an arc threshold current. In addition, the frequency of arc events may be dependent on the current through the electrical contactor 100. An example embodiment of current detection circuitry 338 is depicted in FIG. 5.

Referring now to FIG. 4, an example embodiment of an electrical contactor monitoring system 220 is provided. As depicted in FIG. 4, the example electrical contactor monitoring system 220 includes an electrical contactor device 228 comprising an electrical contactor 100 and an arc sensing system 222. The arc sensing system 222 comprises field monitoring circuitry 332 including a field sensing capacitor, temperature monitoring circuitry 334 including a positive temperature coefficient (PTC) thermistor, and light monitoring circuitry 336 including a photoresistor, each configured to generate arc sensing data 226. As further depicted in FIG. 4, the example electrical contactor monitoring system 220 includes a controller 224 configured to receive arc sensing data 226 from the arc sensing system 222 and transmit control signals 110 to the electrical contactor 100.

As depicted in FIG. 4, the field monitoring circuitry 332 includes a field sensing capacitor. A field sensing capacitor is any electronic component comprising two electrical conductors separated by an insulating material, electrically connected to a portion of the electrical contactor 100 such that the electric field associated with the electrical contactor 100 may be measured. A field sensing capacitor may be associated with any of the conducting surfaces with dielectric in between. In some embodiments, parallel plates may be recreated on the moving and static contact of the electrical contactor 100. For example, a field sensing capacitor may be electrically coupled to one or more conductive surfaces of the electrical contactor (e.g., conductive contact pad 102, power source contact 106). The electric field between the conductive surfaces is directly proportional to the charge on the conductive surfaces and/or voltage difference between the conductive surfaces. Using appropriate measurement technique, the charge accumulated on one or more of the conductive surfaces may be measured. The field sensing capacitor may generate arc sensing data 226 representative of the electric field at the electrical contactor 100. In some embodiments, the electric field may be measured directly based on the charge on the conductive surfaces of the electrical contactor.

As further depicted in FIG. 4, the temperature monitoring circuitry 334 includes a PTC thermistor. A PTC thermistor is any resistive element in which the resistance increases with increased temperature. A PTC thermistor may output arc sensing data 226 representing the contactor temperature at or near the electrical contactor 100. For example, a PTC thermistor may be accompanied by additional circuitry utilized to determine the resistance of the resistive elements at a given point in time. The resistance may then be converted to a temperature. The contactor temperature may indicate the occurrence and/or type of an arc event. For example, an arc event accompanied by an increase in temperature may be identified as a thermionic emission arc event.

As further depicted in FIG. 4, the light monitoring circuitry 336 includes a photoresistor. A photoresistor is any device, sensor, photodiode, or other structure that produces an electric current corresponding to the light received at the photoresistor. A photoresistor is configured to convert photons into an electric current. The electrical contactor monitoring system 220 may determine the light output from and around the electrical contactor 100. Arc events and spark events may be accompanied by a light output, for example, a bright glow. The duration and intensity of the light output may be utilized to determine the arc event type. For example, field emission arc events and thermionic emission arc events may be accompanied by a long duration light output, whereas the light output of a spark event is for a short duration. In some embodiments, the light output of a spark event may be less than 100 milliseconds.

Referring now to FIG. 5, an example embodiment of an electrical contactor monitoring system 220 is provided. As depicted in FIG. 5, the example electrical contactor monitoring system 220 includes an electrical contactor device 228 comprising an electrical contactor 100 and an arc sensing system 222. The arc sensing system 222 comprises current detection circuitry 338 comprising a plurality of current sensing elements 338a-338n, each at a distinct distance 550a-550n from the electrical contactor 100. The current detection circuitry 338 is configured to generate arc sensing data 226 representing the current flowing through the electrical contactor 100. As further depicted in FIG. 5, the example electrical contactor monitoring system 220 includes a controller 224 configured to receive arc sensing data 226 from the arc sensing system 222 and transmit control signals 110 to the electrical contactor 100.

As depicted in FIG. 5, the example current detection circuitry 338 includes a plurality of current sensing elements 338a-338n. A current sensing element 338a-338n is any device configured to output an electrical signal representative of the current through the electrical contactor 100. In some embodiments, the current sensing elements 338a-338n may comprise a Hall effect sensing element. A Hall effect sensing element converts a magnetic field generated by a current carrying conductor into a voltage. A voltage generated by a Hall effect sensing element may be utilized to determine the current passing through the electrical contactor 100.

A Hall effect sensing element may become saturated when exposed to strong magnetic fields. Thus, as depicted in FIG. 5, a plurality of current sensing elements 338a-338n may be positioned at distinct distances 550a-550n from the current carrying electrical contactor 100. In some embodiments, each current sensing element 338a-338n may be positioned to determine a distinct range of current values based on the strength of magnetic field sensed at the distinct distance 550a-550n from the electrical contactor 100. For example, a first current sensing element 338a may be positioned at a first distance 550a and configured to sense a first range of currents (e.g., 0 amps to 50 amps). A second current sensing element 338b may be positioned at a second distance 550b and configured to sense a second range of currents (e.g., 45 amps-500 amps). A third current sensing element 338n may be positioned at a third distance 550n and configured to sense a third range of currents (e.g., 450 amps-1500 amps) and so on. Thus, a wide range of currents may be detected utilizing the current sensing elements 338a-338n. The electrical contactor monitoring system 220 may utilize the current passing through the electrical contactor 100 to identify the occurrence and/or type of arc event. In some embodiments, exceeding an arc event frequency threshold may be indicative the condition of the electrical contactor 100 is in a degraded condition and/or micro welding is occurring. The arc event frequency threshold may be adjusted based on the current passing through the electrical contactor 100 as observed by the current detection circuitry 338.

In some embodiments, the current fluctuations of an alternating current (AC) signal may be identified by the current detection circuitry 338. In such an embodiment, the transitions of the conductive contact pad 102 may be initiated based on the current fluctuations. For example, arc events are more likely to occur and more likely to cause degradation, in an instance in which the current passing through the electrical contactor 100 is high. The current detection circuitry 338 may enable the controller 224 to time the transitions of the conductive contact pad 102 with times in which the current passing through the electrical contactor 100 are lower. Timing the transitions with fluctuations in current may reduce the number of arc events and slow the degradation of the electrical contactor 100.

Referring now to FIG. 6, a graph 660 depicting an example series of arc events 668 over time 664 is provided. Further, as depicted in FIG. 6, the amplitude 662 of the plurality of arc events 668 is provided.

The condition of an electrical contactor (e.g., electrical contactor 100) may be determined based on the detection of arc events (e.g., arc events 668), including the arc event frequency, the arc event type, and the arc event amplitude. For example, an arc event frequency threshold may be determined. An arc event frequency threshold is a frequency of arc events, above which the electrical contactor may be considered to be in a degraded condition. A degraded condition of an electrical contactor indicates an electrical contactor that is or may soon become ineffective. Micro welding may be an indicator of a degraded condition of an electrical contactor. In addition, increased frequency or amplitude of arc events may be an indicator of a degraded condition. Permanent welds are also an indicator of an electrical contactor in a degraded condition. An arc event frequency threshold may vary based on the voltage supplied by a power source utilizing the electrical contactor, the current passing through the electrical contactor, the materials comprising the electrical contactor, and other variables.

The arc event amplitude may be indicated by one or more physical characteristics of the arc event. For example, the light output of the light monitoring circuitry, the electric field observed by the field monitoring circuitry, and/or the contactor temperature observed by the temperature monitoring circuitry may all be utilized as indicators of the amplitude of an arc event 668. In one example embodiment, the peak light output detected by the light monitoring circuitry during an arc event may be determined. The amplitude of the arc event may be determined based on the peak light output. In some embodiments, a combination of the measured characteristics of the arc event 668 may be used to determine an amplitude of the arc event. An arc event amplitude threshold may be determined. An arc event amplitude threshold is any amplitude, above which the electrical contactor is considered to be in a degraded condition. In some embodiments, arc events 668 may be averaged over time to determine an arc event amplitude. An arc event amplitude exceeding an arc event threshold may be considered alone, or in combination with an arc event frequency in determining whether the electrical contactor is in a degraded condition.

As depicted in time period 665 of graph 660, the arc events 668 occur at a relatively low arc event frequency. In addition, the amplitude of the arc events 668 during the time period 665 is relatively low. Such arc event frequency and amplitudes may be indicative of normal operation of an electrical contactor.

As depicted in time period 666 of graph 660, the frequency and amplitude of the arc events 668 has increased compared to time period 665. An increase in arc event 668 frequency and/or an increase in the amplitude of the arc events may be an indicator of a degraded condition of the electrical contactor. In an event that the arc event frequency exceeds an arc event frequency threshold and/or an arc event amplitude exceeds an arc event amplitude threshold, the electrical contactor monitoring system may determine the electrical contactor is in a degraded condition and undertake mitigating actions.

As further depicted in time period 667 of graph 660, the frequency and amplitude of the arc events 668 has increased relative to the time period 666. An increase in arc event 668 frequency and/or an increase in the amplitude of the arc events may be an indicator of a degraded condition of the electrical contactor.

Referring now to FIG. 7, a block diagram of an example controller 224 and accompanying conversion circuitry (e.g., field conversion circuitry 771, temperature conversion circuitry 772, light conversion circuitry 773, current conversion circuitry 774) are provided. As depicted in FIG. 7, the example controller 224 includes an analog-to-digital converter (ADC) 775, an arc classification model 777, and output circuitry 780. The arc classification model 777 further utilizes a thermionic emission arc classifier 776, a field emission arc classifier 778, and a spark classifier 779.

As depicted in FIG. 7, the example conversion circuitry includes field conversion circuitry 771, temperature conversion circuitry 772, light conversion circuitry 773, and current conversion circuitry 774. In general, the conversion circuitry filters, boosts, amplifies, or otherwise prepares the arc sensing data 226 to be processed by the controller 224. For example, field conversion circuitry 771 may comprise a charge amplifier configured to generate an output voltage proportional to the total charge received from the field monitoring circuitry 332. Similarly, the temperature conversion circuitry 772 may include a resistive network configured to generate a voltage proportional to a change in resistance of the resistive elements detected by the PTC thermistor. In some embodiments, the field monitoring circuitry, temperature monitoring circuitry, light monitoring circuitry, and/or current monitoring circuitry may transmit an electric signal as arc sensing data 226 that may be passed directly to the controller 224.

As further depicted in FIG. 7, the controller 224 includes an ADC 775. An ADC 775 may be used to convert analog arc sensing data 226 into a digital representation of the analog data that may be analyzed by the arc classification model 777.

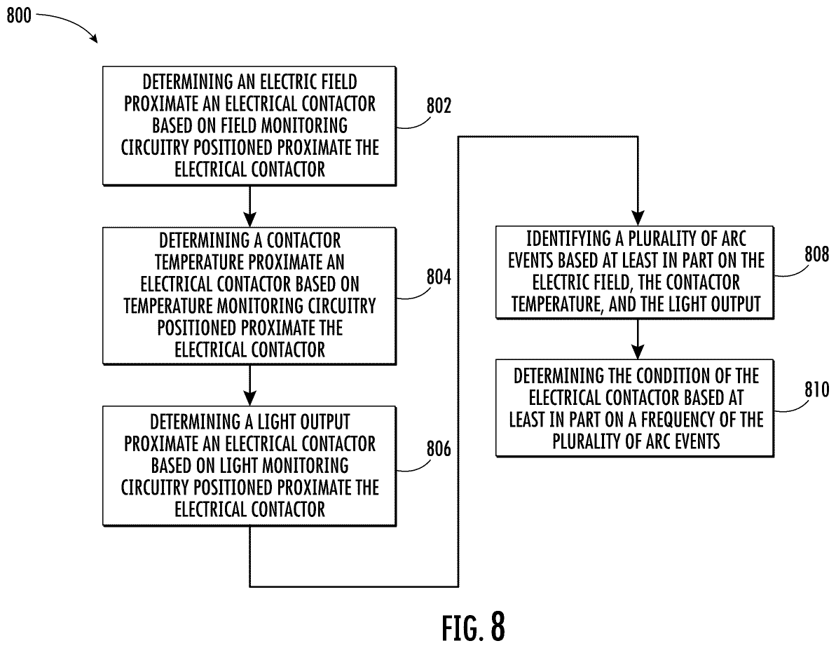

As further depicted in FIG. 7, the controller 224 includes an arc classification model 777. The arc classification model 777 comprises hardware and/or software configured to determine a condition of the electrical contactor based on the arc sensing data 226. The arc classification model 777 may be configured to determine the frequency of occurrence of arc events, the amplitude of arc events, the arc event type, and correlations between arc events. The arc classification model 777 may utilize any technique to identify a condition of the electrical contactor based on the identified arc events. For example, an arc classification model 777 may compare arc events to previously observed thermionic emission arc events. The arc classification model 777 may further determine correlations between arc events and a condition of the electrical contactor. In some embodiments, the arc classification model 777 may utilize learning models to determine correlations between the observed arc events and a condition of the electrical contactor, for example, a degraded condition of the electrical contactor. Functionality associated with the arc classification model 777 is further described in relation to FIG. 8.

In some embodiments, the arc classification model 777 may determine the arc event type of one or more arc events. The arc event type may provide insight into the condition of the electrical contactor.

In one example embodiment, the arc classification model 777 may utilize a thermionic emission arc classifier 776 to identify thermionic emission arc events. A thermionic emission arc event may be distinguishable based on an increased temperature proximate the electrical contactor accompanying a prolonged light output. An arc classification model 777 may utilize any method to identify thermionic emission arc events, including comparisons to previously observed thermionic emission arc events, utilization of learning models, and so forth.

In one example embodiment, the arc classification model 777 may utilize a field emission arc classifier 778 to identify field emission arc events. A field emission arc event may be distinguishable based on an increased electric field proximate the electrical contactor accompanying a prolonged light output. An arc classification model 777 may utilize any method to identify field emission arc events, including comparisons to previously observed field emission arc events, utilization of learning models, and so forth.

In one example embodiment, the arc classification model 777 may utilize a spark classifier 779 to identify spark events. A spark event may be distinguishable based on a shortened light output compared to an arc event. An arc classification model 777 may utilize any method to identify spark events, including comparisons to previously observed spark events, utilization of learning models, and so forth.

As further depicted in FIG. 7, the controller 224 includes output circuitry 780. The output circuitry 780 comprises any circuitry including hardware and/or software configured to transmit condition indicators based on the condition determined by the arc classification model 777. For example, in an instance in which the arc classification model 777 determines an electrical contactor is in a degraded condition, and/or is experiencing micro welds and/or permanent welds, the output circuitry 780 may output a fault mode output indicating the faulty condition of the electrical contactor. Based on a fault mode output, a system may initiate mitigating actions to prevent further degradation of the electrical contactor, for example, by alerting a user or other electrical system.

Referring now to FIG. 8, an example process 800 for determining a condition of an electrical contactor (e.g., electrical contactor 100) is provided. At block 802, a controller (e.g., controller 224) determines an electric field proximate the electrical contactor based on field monitoring circuitry (e.g., field monitoring circuitry 332) positioned proximate the electrical contactor. As described herein, field monitoring circuitry may comprise electrical components configured to determine an electric field at or near the electrical contactor during operation. In some embodiments, the electric field circuitry may determine the electric field between the conductive pad (e.g., conductive contact pad 102) of the electrical contactor and one or more of the conductive surfaces (e.g., power source contact 106, load contact 104). The electric field monitoring circuitry generates an arc sensing data (e.g., arc sensing data 226) representing the observed electric field measurements. Electric field measurements may aid in identifying the type of arc event occurring at the electrical contactor.

At block 804, the controller determines a contactor temperature proximate an electrical contactor based on temperature monitoring circuitry (e.g., temperature monitoring circuitry 334) positioned proximate the electrical contactor. As described herein, temperature monitoring circuitry may comprise electrical components configured to determine a contactor temperature representing the temperature of the environment at or near the electrical contactor. The temperature monitoring circuitry generates arc sensing data representing the observed contactor temperature. The contactor temperature may further aid in identifying the type of arc event occurring at the electrical contactor.

At block 806, the controller determines a light output proximate an electrical contactor based on light monitoring circuitry (e.g., light monitoring circuitry 336) positioned proximate the electrical contactor. As described herein, light monitoring circuitry may comprise electrical components configured to receive light output and generate arc sensing data representing the light output generated at or near the electrical contactor. The duration and intensity of the light output may aid in identifying the type of arc event occurring at the electrical contactor.

At block 808, the controller identifies a plurality of arc events based at least in part on the electric field, the contactor temperature, and the light output. The controller may utilize the various physical characteristics determined by the arc sensing system (e.g., arc sensing system 222) to determine an instance in which an arc event has occurred. For example, a bright flash may be identified based on the light output data from the light monitoring circuitry. Depending on the intensity and the duration of the light output, the bright flash may be classified as an arc event, a spark event, or neither. As an example, light output below a determined threshold intensity may be classified as a non-event. In an instance in which the light output exceeds a threshold intensity, the duration of the light output may be utilized to distinguish between a spark event and an arc event. As an example, light output meeting the threshold intensity and continuing longer than a minimum arc duration may be classified as an arc event, while light output meeting the threshold intensity but lasting shorter than the minimum arc duration may be classified as a spark event.

Further physical characteristics may be leveraged to further identify an arc event type. For example, an increase in the electric field proximate the electrical contactor at the time of an arc event may indicate a field emission arc event. Similarly, an increase in contactor temperature proximate the electrical contactor at the time of an arc event may indicate a thermionic emission arc.

At block 810, the controller determines the condition of the electrical contactor based at least in part on a frequency of the plurality of arc events. During arc events, the conductive materials comprising the conductive contact pad, the power source contact, and the load contact of the electrical contactor are heated. The heating may result in the softening, melting, and boiling of the conductive materials. Repeated heating and cooling of the conductive materials may lead to micro welding between the conductive contact pad and the conductive surfaces (e.g., load contact 104, power source contact 106). Micro welding may result in temporary adhesion between the conductive contact pad and the conductive surfaces at spot locations. An increased frequency in arc events may increase the likelihood that micro welding and subsequent permanent welding may occur. In addition, micro welding may result in bounce arcs. Bounce arcs occur during a transition of an electrical contactor from a disconnected state to a connected state or a transition from a connected state to a disconnected state. Micro welds may cause the conductive contact pad to bounce, causing multiple arcs to occur in a short duration.

Thus, an increase in frequency of arc events at an electrical contactor may be an indication of a degraded condition of the electrical contactor. The controller may utilize any mechanism to track the frequency of arc events at an electrical contactor. The controller may further utilize various characteristics to determine an instance in which the frequency of arc events is indicative of a degraded condition of the electrical contactor. For example, the controller may consider the current passing through the electrical contactor, the voltage across an electrical contactor, the arc event types, the intensity of the arc events, the duration of arc events, and so on when determining whether an electrical contactor is in a degraded condition.

As described herein, increased arc events may be an indication that the electrical contactor is in a degraded condition. A degraded condition may be accompanied by micro welds, metallic debris and corrosion on the conductive surfaces of the electrical contactor, and other issues affecting the performance of the electrical contactor. A degraded condition is a warning that permanent welding, or another hazardous condition of the electrical contactor may be imminent. By identifying the degraded condition of the electrical contactor based on the frequency of arc events, a catastrophic event may be avoided.

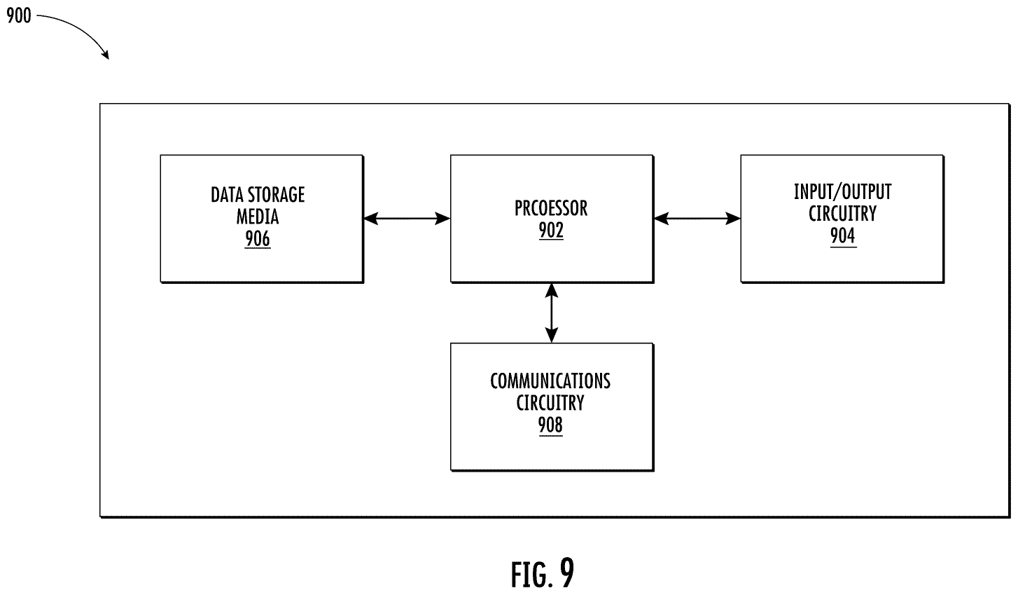

Referring not to FIG. 9, FIG. 9 illustrates an example controller 224 in accordance with at least some example embodiments of the present disclosure. The controller 224 includes processor 902, input/output circuitry 904, data storage media 906, and communications circuitry 908. In some embodiments, the controller 224 is configured, using one or more of the sets of circuitry 902, 904, 906, and/or 908, to execute and perform the operations described herein.

Although components are described with respect to functional limitations, it should be understood that the particular implementations necessarily include the use of particular computing hardware. It should also be understood that in some embodiments certain of the components described herein include similar or common hardware. For example, two sets of circuitry may both leverage use of the same processor(s), network interface(s), storage medium(s), and/or the like, to perform their associated functions, such that duplicate hardware is not required for each set of circuitry. The user of the term “circuitry” as used herein with respect to components of the apparatuses described herein should therefore be understood to include particular hardware configured to perform the functions associated with the particular circuitry as described herein.

Particularly, the term “circuitry” should be understood broadly to include hardware and, in some embodiments, software for configuring the hardware. For example, in some embodiments, “circuitry” includes processing circuitry, storage media, network interfaces, input/output devices, and/or the like. Alternatively, or additionally, in some embodiments, other elements of the controller 224 provide or supplement the functionality of other particular sets of circuitry. For example, the processor 902 in some embodiments provides processing functionality to any of the sets of circuitry, the data storage media 906 provides storage functionality to any of the sets of circuitry, the communications circuitry 908 provides network interface functionality to any of the sets of circuitry, and/or the like.

In some embodiments, the processor 902 (and/or co-processor or any other processing circuitry assisting or otherwise associated with the processor) is/are in communication with the data storage media 906 via a bus for passing information among components of the controller 224. In some embodiments, for example, the data storage media 906 is non-transitory and may include, for example, one or more volatile and/or non-volatile memories. In other words, for example, the data storage media 906 in some embodiments includes or embodies an electronic storage device (e.g., a computer readable storage medium). In some embodiments, the data storage media 906 is configured to store information, data, content, applications, instructions, or the like, for enabling the controller 224 to carry out various functions in accordance with example embodiments of the present disclosure.

The processor 902 may be embodied in a number of different ways. For example, in some example embodiments, the processor 902 includes one or more processing devices configured to perform independently. Additionally, or alternatively, in some embodiments, the processor 902 includes one or more processor(s) configured in tandem via a bus to enable independent execution of instructions, pipelining, and/or multithreading. The use of the terms “processor” and “processing circuitry” should be understood to include a single core processor, a multi-core processor, multiple processors internal to the controller 224, and/or one or more remote or “cloud” processor(s) external to the controller 224.

In an example embodiment, the processor 902 is configured to execute instructions stored in the data storage media 906 or otherwise accessible to the processor. Alternatively, or additionally, the processor 902 in some embodiments is configured to execute hard-coded functionality. As such, whether configured by hardware or software methods, or by a combination thereof, the processor 902 represents an entity (e.g., physically embodied in circuitry) capable of performing operations according to an embodiment of the present disclosure while configured accordingly. Alternatively, or additionally, as another example in some example embodiments, when the processor 902 is embodied as an executor of software instructions, the instructions specifically configure the processor 902 to perform the algorithms embodied in the specific operations described herein when such instructions are executed.

In some embodiments, the controller 224 includes input/output circuitry 904 that provides output to the user and, in some embodiments, to receive an indication of a user input. In some embodiments, the input/output circuitry 904 is in communication with the processor 902 to provide such functionality. The input/output circuitry 904 may comprise one or more user interface(s) (e.g., user interface) and in some embodiments includes a display that comprises the interface(s) rendered as a web user interface, an application user interface, a user device, a backend system, or the like. The processor 902 and/or input/output circuitry 904 comprising the processor may be configured to control one or more functions of one or more user interface elements through computer program instructions (e.g., software and/or firmware) stored on a memory accessible to the processor (e.g., data storage media 906, and/or the like). In some embodiments, the input/output circuitry 904 includes or utilizes a user-facing application to provide input/output functionality to a client device and/or other display associated with a user.

In some embodiments, the controller 224 includes communications circuitry 908. The communications circuitry 908 includes any means such as a device or circuitry embodied in either hardware or a combination of hardware and software that is configured to receive and/or transmit data from/to a network and/or any other device, circuitry, or module in communication with the controller 224. In this regard, the communications circuitry 908 includes, for example in some embodiments, a network interface for enabling communications with a wired or wireless communications network. Additionally, or alternatively in some embodiments, the communications circuitry 908 includes one or more network interface card(s), antenna(s), bus(es), switch(es), router(s), modem(s), and supporting hardware, firmware, and/or software, or any other device suitable for enabling communications via one or more communications network(s). Additionally, or alternatively, the communications circuitry 908 includes circuitry for interacting with the antenna(s) and/or other hardware or software to cause transmission of signals via the antenna(s) or to handle receipt of signals received via the antenna(s). In some embodiments, the communications circuitry 908 enables transmission to and/or receipt of data from a client device in communication with the controller 224.

Additionally, or alternatively, in some embodiments, one or more of the sets of circuitry 902-908 are combinable. Additionally, or alternatively, in some embodiments, one or more of the sets of circuitry perform some or all of the functionality described associated with another component. For example, in some embodiments, one or more sets of circuitry 902-908 are combined into a single module embodied in hardware, software, firmware, and/or a combination thereof. Similarly, in some embodiments, one or more of the sets of circuitry is/are combined such that the processor 902 performs one or more of the operations described above with respect to each of these circuitry individually.

Many modifications and other embodiments of the inventions set forth herein will come to mind to one skilled in the art to which these inventions pertain having the benefit of teachings presented in the foregoing descriptions and the associated drawings. Although the figures only show certain components of the apparatus and systems described herein, it is understood that various other components may be used in conjunction with the system. Therefore, it is to be understood that the inventions are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. The disclosed embodiments relate primarily to an electrical contactor, however, one skilled in the art may recognize that such principles may be applied to any electrical component configured to selectively and repeatedly connect a power source to an electrical load using mechanical means. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the invention(s) set out in any claims that may issue from this disclosure.

Use of broader terms such as “comprises,” “includes,” and “having” should be understood to provide support for narrower terms such as “consisting of,” “consisting essentially of,” and “comprised substantially of” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

1. An apparatus comprising:
field monitoring circuitry positioned proximate an electrical contactor and configured to determine an electric field proximate the electrical contactor;
temperature monitoring circuitry positioned proximate the electrical contactor and configured to determine a contactor temperature proximate the electrical contactor; and,
light monitoring circuitry positioned proximate the electrical contactor and configured to determine a light output proximate the electrical contactor, wherein a plurality of arc events of the electrical contactor are identified based at least in part on the electric field, the contactor temperature, and the light output, and wherein a condition of the electrical contactor is determined based at least in part on a frequency of the plurality of arc events.

2. The apparatus of claim 1, further comprising current detection circuitry, wherein the current detection circuitry is configured to determine a current through the electrical contactor.

3. The apparatus of claim 2, the current detection circuitry comprising a plurality of current sensing elements comprising at least a first current sensing element and a second current sensing element, wherein the first current sensing element is positioned at a first distance from the electrical contactor and the second current sensing element is positioned at a second distance from the electrical contactor, and wherein the second distance is greater than the first distance.

4. The apparatus of claim 2, wherein the condition of the electrical contactor is determined based at least in part on the current through the electrical contactor.

5. The apparatus of claim 1, wherein the field monitoring circuitry comprises a field sensing capacitor.

6. The apparatus of claim 1, wherein the temperature monitoring circuitry comprises a positive temperature coefficient (PTC) sensor.

7. The apparatus of claim 1, wherein the light monitoring circuitry comprises a photoresistor.

8. The apparatus of claim 1, wherein the plurality of arc events are classified according to an arc event type.

9. The apparatus of claim 8, wherein the arc event type comprises at least one of a field emission arc event, a thermionic emission arc event, and a spark event.

10. The apparatus of claim 1, wherein the condition of the electrical contactor is a degraded condition.

11. The apparatus of claim 1, wherein the condition is determined based at least in part on an amplitude of the plurality of arc events.

12. A computer-implemented method for determining a condition of an electrical contactor, comprising:
determining an electric field proximate an electrical contactor based on field monitoring circuitry positioned proximate the electrical contactor;
determining a contactor temperature proximate an electrical contactor based on temperature monitoring circuitry positioned proximate the electrical contactor;
determining a light output proximate an electrical contactor based on light monitoring circuitry positioned proximate the electrical contactor;
identifying a plurality of arc events based at least in part on the electric field, the contactor temperature, and the light output; and,
determining the condition of the electrical contactor based at least in part on a frequency of the plurality of arc events.

13. The computer-implemented method of claim 12, further comprising determining a current through the electrical contactor based on current detection circuitry positioned proximate the electrical contactor.

14. The computer-implemented method of claim 13, wherein the condition of the electrical contactor is determined based at least in part on the current through the electrical contactor.

15. The computer-implemented method of claim 12, wherein the field monitoring circuitry comprises a field sensing capacitor.

16. The computer-implemented method of claim 12, wherein the temperature monitoring circuitry comprises a positive temperature coefficient (PTC) sensor.

17. The computer-implemented method of claim 12, wherein the light monitoring circuitry comprises a photoresistor.

18. The computer-implemented method of claim 12, further comprising:
classifying the plurality of arc events according to an arc event type.

19. The computer-implemented method of claim 18, wherein the arc event type comprises at least one of a field emission arc event, a thermionic emission arc event, and a spark event.

20. An electrical system comprising:
an electrical contactor configured to selectively provide an electrical connection between a power source and an electrical load;
field monitoring circuitry positioned proximate the electrical contactor and configured to determine an electric field proximate the electrical contactor;
temperature monitoring circuitry positioned proximate the electrical contactor and configured to determine a contactor temperature proximate the electrical contactor;
light monitoring circuitry positioned proximate the electrical contactor and configured to determine a light output proximate the electrical contactor; and,
a controller configured to:
determine an electric field proximate an electrical contactor based on field monitoring circuitry positioned proximate the electrical contactor;
determine a contactor temperature proximate an electrical contactor based on temperature monitoring circuitry positioned proximate the electrical contactor;
determine a light output proximate an electrical contactor based on light monitoring circuitry positioned proximate the electrical contactor;
identify a plurality of arc events based at least in part on the electric field, the contactor temperature, and the light output; and,
determine a condition of the electrical contactor based at least in part on a frequency of the plurality of arc events.
